(19) United States
(12) Patent Application Publication
(10) Pub. No.: US 2019/0131113 A1
(43) Pub. Date: May 2, 2019

(54) Y2O3-SiO2 PROTECTIVE COATINGS FOR SEMICONDUCTOR PROCESS CHAMBER COMPONENTS

(71) Applicant: Applied Materials, Inc., Santa Clara, CA (US)

(72) Inventors: David Fenwick, Los Altos Hills, CA (US); Jennifer Y. Sun, Mountain View, CA (US)

(21) Appl. No.: 16/177,215

(22) Filed: Oct. 31, 2018

Related U.S. Application Data
(60) Provisional application No. 62/580,583, filed on Nov. 2, 2017.

(51) Int. Cl. H01J 37/32; C23C 14/34; C23C 14/08; C23C 14/14; C23C 16/455; C23C 16/40

(52) U.S. Cl. CPC H01J 37/32495; C23C 14/3442; C23C 14/083; C23C 14/14; C23C 16/45565; H01J 2237/3321; C23C 16/405; C23C 16/402; H01J 37/32715; H01J 37/32642; H01J 2237/3341; C23C 16/45527

(57) ABSTRACT

A semiconductor process chamber component including an article coated with a protective coating that may have Y₂O₃ at a concentration of about 10 molar % to about 65 molar % and SiO₂ at a concentration of about 35 molar % to about 90 molar %.

### RELATED APPLICATIONS

This application claims priority to U.S. Provisional Patent Application No. 62/580,583, filed Nov. 2, 2017, which is herein incorporated by reference in its entirety.

### TECHNICAL FIELD

Embodiments disclosed herein relate, in general, to protective coatings for semiconductor process chamber components, and in particular to corrosion and/or erosion resistant ceramic material coatings for semiconductor process chamber components.

### BACKGROUND

In the semiconductor industry, devices are fabricated by a number of manufacturing processes producing structures of an ever-decreasing size. Some manufacturing processes such as plasma etch and plasma clean processes expose a substrate to a high-speed stream of plasma to etch or clean the substrate. The plasma may be highly corrosive, and may corrode processing chambers and other surfaces that are exposed to the plasma. This corrosion may generate particles, which frequently contaminate the substrate that is being processed, contributing to device defects. Additionally, the corrosion may cause metal atoms from chamber components to contaminate processed substrates (e.g., processed wafers).

As device geometries shrink, susceptibility to defects and particle contamination increases, and particle contaminant specifications become more stringent. To minimize defects and particle contamination introduced by chamber components during chamber processing, chamber components and chamber component coatings that are resistant to chamber processing conditions and are less likely to generate particles with the potential of contaminating a processed substrate are being developed.

### SUMMARY

In an example embodiment, a semiconductor process chamber component may comprise an article and a protective ceramic material coating. The protective ceramic material coating may comprise at least one phase material. The at least one phase material may comprise Y₂O₃ at a concentration of about 10 molar % to about 65 molar % and SiO₂ at a concentration of about 35 molar % to about 90 molar %.

In an example embodiment, a method for coating an article may comprise creating a mixture of ceramic powders to form a protective ceramic material coating. The mixture of ceramic powders may comprise Y₂O₃ at a concentration of about 10 molar % to about 65 molar % and SiO₂ at a concentration of about 35 molar % to about 90 molar %. The method may further comprise coating an article with a protective ceramic material coating.

In an example embodiment, a semiconductor process chamber component coating may comprise at least one phase material. The at least one phase material may comprise Y₂O₃ at a concentration of about 10 molar % to about 65 molar % and SiO₂ at a concentration of about 35 molar % to about 90 molar %.

### BRIEF DESCRIPTION OF THE DRAWINGS

The present invention is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a sectional view of a semiconductor processing chamber having one or more chamber components that are coated with a protective coating material provided in embodiments herein.

FIG. 2 is a sectional view of a coated article, in accordance with an embodiment.

FIG. 3 discloses a method for coating an article, in accordance with an embodiment.

FIG. 4A depicts a deposition mechanism applicable to a variety of deposition techniques utilizing energetic particles such as ion assisted deposition (IAD).

FIG. 4B depicts a schematic of an IAD deposition apparatus that may be utilized for coating an article, in accordance with an embodiment.

FIG. 5 depicts an exemplary CVD system that may be utilized for coating an article, in accordance with an embodiment.

FIG. 6 depicts an exemplary PVD system that may be utilized for coating an article, in accordance with an embodiment.

FIG. 7 illustrates a cross-sectional view of a system for plasma spraying a protective coating on an article, in accordance with an embodiment.

FIG. 8 depicts a mechanism applicable to a variety of ALD techniques that may be utilized for coating an article, in accordance with an embodiment.

### DETAILED DESCRIPTION OF EMBODIMENTS

Embodiments disclosed herein are directed to protective ceramic material coatings, semiconductor process chamber components coated with a protective ceramic material coating, and processes of coating articles, e.g. semiconductor process chamber components, with a protective ceramic material coating. The protective ceramic material coating may have at least one phase material and an overall composition that includes Y₂O₃ at a concentration of about 10 molar % to about 65 molar %, about 20 molar % to about 60 molar %, about 25 molar % to about 55 molar %, or about 40 molar % to about 50 molar % and SiO₂ at a concentration of about 35 molar % to about 90 molar %, about 40 molar % to about 80 molar %, about 45 molar % to about 75 molar %, or about 50 molar % to about 60 molar %. The protective ceramic material coating may be deposited by various techniques, including but not limited to, ion assisted deposition (IAD) (e.g., using electron beam IAD (EB-IAD) or ion beam sputtering IAD (IBS-IAD)), physical vapor deposition (PVD), chemical vapor deposition (CVD), atomic layer deposition (ALD), plasma spray, etc . . . . Use of chamber components coated with the protective ceramic material coating described herein may reduce yttrium metal contamination on processed wafers and also minimize particle generation, and enhance erosion and/or corrosion resistance of coated chamber components.

When the terms “about” and “approximate” are used herein, this is intended to mean that the nominal value presented is precise within ±10%.

When the phrase “at least one phase material” is used herein, it refers to a material that includes at least one state of matter but could also include a plurality of phases (i.e. state of matters) or a mixture of phases (i.e. state of matters) at the same time. For instance, a single phase may refer to a solid solution, whereas a plurality of phases may refer to a mixture of two or more solid phases.

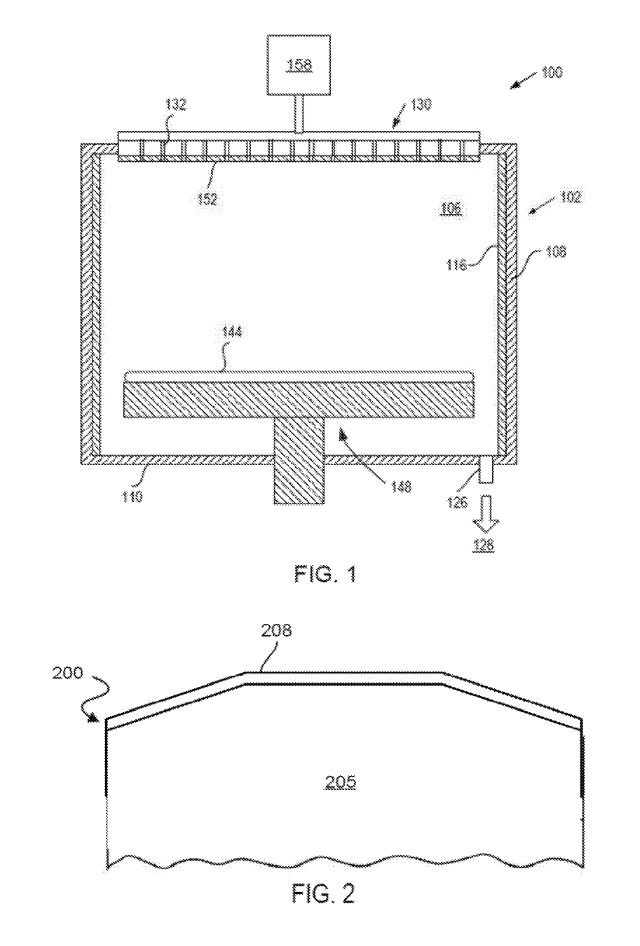

FIG. 1 is a sectional view of a processing chamber 100 (e.g., a semiconductor processing chamber) having one or more chamber components that include a protective coating in accordance with embodiments. The processing chamber 100 may be used for processes in which a corrosive plasma environment is provided. For example, the processing chamber 100 may be a chamber for a plasma etch reactor (also known as a plasma etcher), a plasma cleaner, and so forth. Examples of chamber components that may include a protective coating are a substrate support assembly 148, an electrostatic chuck (ESC), a ring (e.g., a process kit ring or single ring), a chamber wall, a base, a showerhead 130, a gas distribution plate, a liner, a liner kit, a gas line, a shield, a plasma screen, a flow equalizer, a cooling base, a chamber viewport, a chamber lid, a nozzle, and so on.

In one embodiment, the processing chamber 100 includes a chamber body 102 and a showerhead 130 that enclose an interior volume 106. The showerhead 130 may or may not include a gas distribution plate. For example, the showerhead may be a multi-piece showerhead that includes a showerhead base and a showerhead gas distribution plate bonded to the showerhead base. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material. The chamber body 102 generally includes sidewalls 108 and a bottom 110.

An outer liner 116 may be disposed adjacent the sidewalls 108 to protect the chamber body 102. The outer liner 116 may be a halogen-containing gas resistant material such as Al₂O₃ or Y₂O₃. The outer liner 116 may also be coated with a protective ceramic material coating, in accordance with an embodiment.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewalls 108 of the chamber body 102 and/or on a top portion of the chamber body. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 includes multiple gas delivery holes 132 throughout the showerhead 130. The showerhead 130 may be aluminum, anodized aluminum, an aluminum alloy (e.g., Al 6061), or an anodized aluminum alloy. In some embodiments, the showerhead includes a gas distribution plate (GDP) bonded to the showerhead. The GDP may be, for example, Si or SiC. The GDP may additionally include multiple holes that line up with the holes in the showerhead.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, Cl₂, CCl₄, BCl₃ and SiF₄, among others, and other gases such as O₂, or N₂O. Examples of carrier gases include N₂, He, Ar, and other gases inert to process gases (e.g., non-reactive gases).

A substrate support assembly 148 is disposed in the interior volume 106 of the processing chamber 100 below the showerhead 130. The substrate support assembly 148 holds a substrate 144 (e.g., a wafer) during processing. The substrate support assembly 148 may include an electrostatic chuck that secures the substrate 144 during processing, a metal cooling plate bonded to the electrostatic chuck, and/or one or more additional components. An inner liner (not shown) may cover a periphery of the substrate support assembly 148. The inner liner may be a halogen-containing gas resistant material such as Al₂O₃ or Y₂O₃. The inner liner may also be coated with a protective ceramic material coating, in accordance with an embodiment.

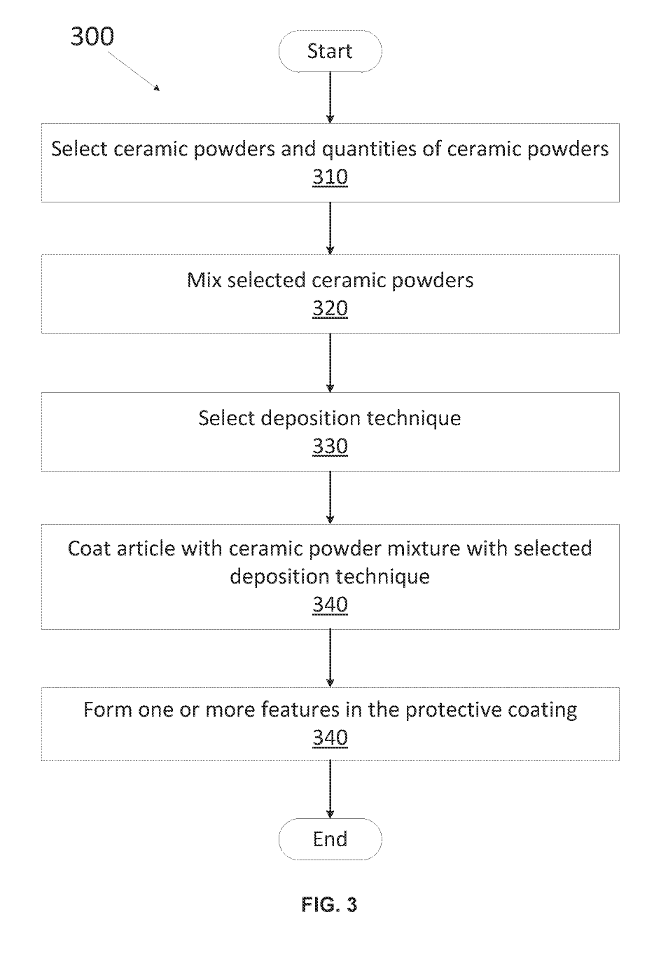

Any of the showerhead 130 (or lid and/or nozzle), sidewalls 108, bottom 110, substrate support assembly 148, outer liner 116, inner liner (not shown), or other chamber component may include a protective coating, in accordance with embodiments. For example, as shown showerhead 130 includes a protective coating 152. In some embodiments, the protective coating 152 may be a protective ceramic material coating. In some embodiments, the protective ceramic material coating may comprise at least one phase material of Y₂O₃ and SiO₂. The protective ceramic material coating is described in more detail with reference to FIG. 2 and the process of coating an article with the protective ceramic material coating is described in more detail with reference to FIG. 3.

FIG. 2 is a sectional view of a coated semiconductor process chamber component 200, in accordance with an embodiment. In an embodiment, the coated semiconductor process chamber component may comprise an article 205 and a protective ceramic material coating 208.

Exemplary articles may be selected from the group consisting of an electrostatic chuck, a nozzle, a gas distribution plate, a shower head, an electrostatic chuck component, a chamber wall, a liner, a liner kit, a gas line, a chamber lid, a nozzle, a single ring and a processing kit ring.

The protective ceramic material coating may comprise yttria (Y₂O₃), silica (SiO₂), or a combination thereof, such as a solid solution of yttria and silica or a multiphase mixture. In certain embodiments, the protective ceramic material coating may be predominantly yttria and a portion of the protective ceramic material coating may be substituted with silica so as to minimize the potential of yttrium metal contaminants getting deposited on substrates during processing.

In one embodiment, the protective ceramic material coating may comprise at least one phase material of yttria and silica. In certain embodiments, the protective ceramic material coating may consist of or consist essentially of at least one phase material of yttria and silica. In certain embodiments, the concentration of Y₂O₃ and of SiO₂ adds up to 100 molar %. In other embodiments, the at least one phase material may comprise additional constituents other than Y₂O₃ and SiO₂. In one embodiment, the protective ceramic material coating may consist of only Y₂O₃ and SiO₂ (in the form of one or more phases).

In one embodiment, the at least one phase material may comprise Y₂O₃ at a concentration of about 10 molar % to about 65 molar % and SiO₂ at a concentration of about 35 molar % to about 90 molar % to. In one embodiment, the at least one phase material may comprise Y₂O₃ at a concentration of about 20 molar % to about 60 molar % and SiO₂ at a concentration of about 40 molar % to about 80 molar %. In one embodiment, the at least one phase material may comprise Y₂O₃ at a concentration of about 25 molar % to about 55 molar % and SiO₂ at a concentration of about 45 molar % to about 75 molar %. In one embodiment, the at least one phase material may comprise Y₂O₃ at a concentration of about 40 molar % to about 50 molar % and SiO₂ at a concentration of about 50 molar % to about 60 molar %.

In one embodiment, the at least one phase material may comprise a composition selected from the group consisting of: a) Y₂O₃ at a concentration of about 65 molar % and SiO₂ at a concentration of about 35 molar %, b) Y₂O₃ at a concentration of about 60 molar % and SiO₂ at a concentration of about 40 molar %, c) Y₂O₃ at a concentration of about 55 molar % and SiO₂ at a concentration of about 45 molar %, d) Y₂O₃ at a concentration of about 50 molar % and SiO₂ at a concentration of about 50 molar %, e) Y₂O₃ at a concentration of about 45 molar % and SiO₂ at a concentration of about 55 molar %, f) Y₂O₃ at a concentration of about 40 molar % and SiO₂ at a concentration of about 60 molar %, g) Y₂O₃ at a concentration of about 35 molar % and SiO₂ at a concentration of about 65 molar %, h) Y₂O₃ at a concentration of about 30 molar % and SiO₂ at a concentration of about 70 molar %, i) Y₂O₃ at a concentration of about 25 molar % and SiO₂ at a concentration of about 75 molar %, j) Y₂O₃ at a concentration of about 20 molar % and SiO₂ at a concentration of about 80 molar %, k) Y₂O₃ at a concentration of about 15 molar % and SiO₂ at a concentration of about 85 molar %, and l) Y₂O₃ at a concentration of about 10 molar % and SiO₂ at a concentration of about 90 molar %.

Any of the aforementioned protective coatings may include trace amounts of other materials such as ZrO₂, Al₂O₃, SiO₂, B₂O₃, Er₂O₃, Nd₂O₃, Nb₂O₅, CeO₂, Sm₂O₃, Yb₂O₃, or other oxides.

In one embodiment, EB-IAD is utilized to form the protective ceramic material coat 208. In one embodiment, IBS-IAD is utilized to form the protective ceramic material coat 208. In one embodiment, CVD is utilized to form the protective ceramic material coat 208. In one embodiment, PVD is utilized to form the protective ceramic material coat 208. In one embodiment, plasma spray is utilized to form the protective ceramic material coat 208. In one embodiment, ALD is utilized to form the protective ceramic material coat 208.

FIG. 3 is a flow chart showing a method 300 for coating an article, such as a semiconductor process chamber component, in accordance with one embodiment. At block 310, ceramic powders that are to be used to form the protective coat are selected. Quantities of the selected ceramic powders are also selected.

In one embodiment, the selected ceramic powders comprise Y₂O₃, SiO₂, or a combination thereof. In one embodiment, the selected ceramic powders may consist of or consist essentially of yttria and silica. In certain embodiments, the concentration of Y₂O₃ and of SiO₂ powders adds up to 100 molar %. In other embodiments, the selected ceramic powders may comprise additional constituents other than Y₂O₃ and SiO₂.

In one embodiment, the ceramic powders include Y₂O₃ at a concentration of about 10 molar % to about 65 molar % and SiO₂ at a concentration of about 35 molar % to about 90 molar % to. In one embodiment, the selected ceramic powders include Y₂O₃ at a concentration of about 20 molar % to about 60 molar % and SiO₂ at a concentration of about 40 molar % to about 80 molar %. In one embodiment, the selected ceramic powders include Y₂O₃ at a concentration of about 25 molar % to about 55 molar % and SiO₂ at a concentration of about 45 molar % to about 75 molar %. In one embodiment, the selected ceramic powders include Y₂O₃ at a concentration of about 40 molar % to about 50 molar % and SiO₂ at a concentration of about 50 molar % to about 60 molar %.

In one embodiment, the selected ceramic powders include a composition selected from the group consisting of: a) Y₂O₃ at a concentration of about 65 molar % and SiO₂ at a concentration of about 35 molar %, b) Y₂O₃ at a concentration of about 60 molar % and SiO₂ at a concentration of about 40 molar %, c) Y₂O₃ at a concentration of about 55 molar % and SiO₂ at a concentration of about 45 molar %, d) Y₂O₃ at a concentration of about 50 molar % and SiO₂ at a concentration of about 50 molar %, e) Y₂O₃ at a concentration of about 45 molar % and SiO₂ at a concentration of about 55 molar %, f) Y₂O₃ at a concentration of about 40 molar % and SiO₂ at a concentration of about 60 molar %, g) Y₂O₃ at a concentration of about 35 molar % and SiO₂ at a concentration of about 65 molar %, h) Y₂O₃ at a concentration of about 30 molar % and SiO₂ at a concentration of about 70 molar %, i) Y₂O₃ at a concentration of about 25 molar % and SiO₂ at a concentration of about 75 molar %, j) Y₂O₃ at a concentration of about 20 molar % and SiO₂ at a concentration of about 80 molar %, k) Y₂O₃ at a concentration of about 15 molar % and SiO₂ at a concentration of about 85 molar %, and l) Y₂O₃ at a concentration of about 10 molar % and SiO₂ at a concentration of about 90 molar %.

At block 320, the selected ceramic powders are mixed. In some embodiment, the selected powders may be mixed with other components, including but not limited to, water, a binder, or a deflocculant to form a slurry.

At block 330, a deposition technique is selected for coating the article with the protective ceramic material coating. The deposition technique may be selected, without limitations, from the group consisting of IAD, CVD, PVD, ALD, and plasma spray.

At block 340, the ceramic powders mixture may be deposited on an article, such as a semiconductor process chamber component, using the deposition technique selected at block 330.

The article coated may be a semiconductor process chamber component selected, without limitations, from the group consisting of an electrostatic chuck, a lid, a nozzle, a gas distribution plate, a shower head, an electrostatic chuck component, a chamber wall, a liner, a liner kit, a chamber lid, a single ring, a processing kit ring, a gas line, and combinations thereof.

The protective ceramic material coating may be coated over different ceramic articles including oxide based ceramics, nitride based ceramics and carbide based ceramics. Examples of oxide based ceramics include SiO₂ (quartz), Al₂O₃, Y₂O₃, and so on. Examples of carbide based ceramics include SiC, Si—SiC, and so on. Examples of nitride based ceramics include AN, SiN, and so on. The protective ceramic material coating may also be applied over a plasma sprayed protective layer. The plasma sprayed protective layer may be Y₃Al₅O₁₂, Y₂O₃, Y₄Al₂O₉, Er₂O₃, Gd₂O₃, Er₃Al₅O₁₂, Gd₃Al₅O₁₂, a ceramic compound comprising Y₄Al₂O₉ and a solid-solution of Y₂O₃—ZrO₂, or another ceramic.

In some embodiments, the method of coating an article with a protective ceramic material coating may further comprise forming one or more features in the protective ceramic material coating, in accordance with block 350. Forming one or more features may include grinding and/or polishing the protective ceramic material coating, drilling holes in the protective ceramic material coating, cutting and/or shaping the protective ceramic material coating, roughening the protective ceramic material coating (e.g., by bead blasting), forming mesas on the protective ceramic material coating, and so forth. In one embodiment, the one or more features may comprise at least one of holes, channels, or mesas.

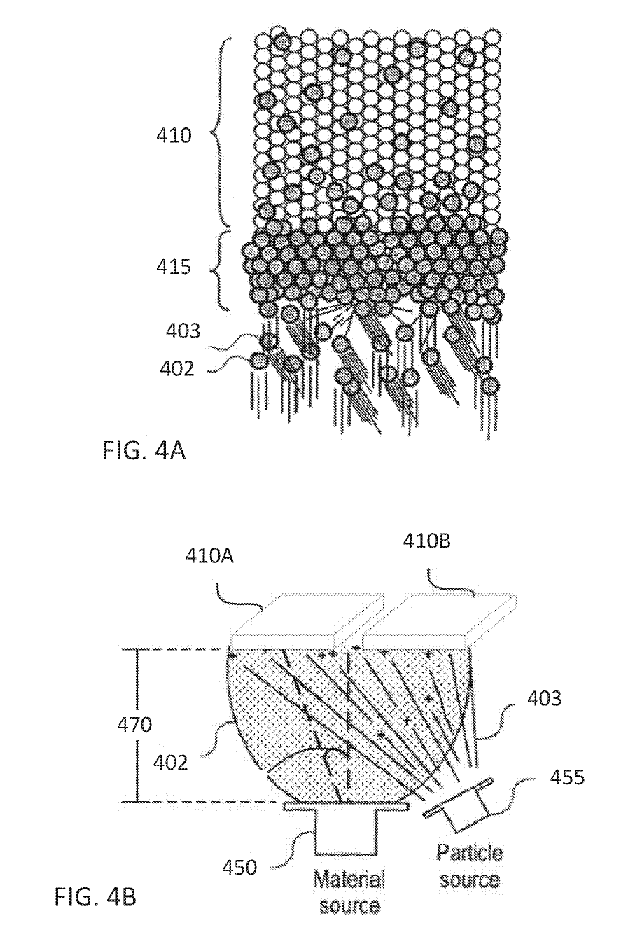

FIG. 4A depicts a deposition mechanism applicable to a variety of deposition techniques utilizing energetic particles such as IAD. Exemplary IAD methods include deposition processes which incorporate ion bombardment, such as evaporation (e.g., activated reactive evaporation (ARE) or electron beam ion assisted deposition (EB-IAD)) and sputtering (e.g., ion beam sputtering ion assisted deposition (IBS-IAD)) in the presence of ion bombardment to form protective coatings as described herein. EB-IAD may be performed by evaporation. IBS-IAD may be performed by sputtering a solid material source. Any of the IAD may be performed in the presence of a reactive gas species (e.g., O₂, N₂, CO, halogens, etc) and/or in the presence of non-reactive species (e.g., Ar).

As shown, the protective coat 415 is formed on an article 410 or on multiple articles 410A, 410B (shown in FIG. 4B) by an accumulation of deposition materials 402 in the presence of energetic particles 403 such as ions (e.g., oxygen ions or nitrogen ions). The deposition materials 402 may include atoms, ions, radicals, or their mixture. The energetic particles 403 may impinge and compact the protective coat 415 as it is formed.

FIG. 4B depicts a schematic of an IAD apparatus. As shown, a material source 450 provides a flux of deposition materials 402 while an energetic particle source 455 provides a flux of the energetic particles 403, both of which impinge upon the article 410 (shown in FIG. 4A), 410A, 410B throughout the IAD process. The energetic particle source 455 may be an oxygen, nitrogen or other ion source. The energetic particle source 455 may also provide other types of energetic particles such as inert radicals, neutron atoms, and nano-sized particles which come from particle generation sources (e.g., from plasma, reactive gases or from the material source that provide the deposition materials). IAD may utilize one or more plasmas (for example, argon plasma or argon-oxygen plasma) or beams to provide the material and energetic particles sources. Reactive species may also be provided during deposition of the plasma resistant coating.

With IAD processes, energetic particles 403 may be controlled by the energetic particle source 455 (e.g., energetic ion source) independently of other deposition parameters. The energy (e.g., velocity), density, working distance and incident angle of the energetic particle flux may be adjusted to control a composition, structure, crystalline orientation and grain size of the protective coat. Additional parameters that may also be adjusted are the article's temperature during deposition as well as the duration of the deposition. In certain embodiments, the deposition temperature (i.e., the temperature in the deposition chamber and the article therein) ranges from about 160° C. to about 500° C. or from about 200° C. to about 270° C. In certain embodiments, the working distance 470 between the material source 450 and the article 410A, 410B range from about 0.2 to about 2.0 meters or from about 0.2 to about 1.0 meters. In certain embodiments, the protective coating may have a non-uniformity of up to about 5-10%. In certain embodiments, the incident angle (i.e. the angle at which the deposition material from the material source strike the article) ranges from about 10-90 degrees or may be about 30 degrees.

IAD coatings can be applied over a wide range of surface conditions with roughness from about 0.5 micro-inches (On) to about 180 μin. However, smoother surface facilitates uniform coating coverage. The coating thickness can be up to about 1000 micrometers (μm). IAD coatings can be amorphous or crystalline depending on the material used to create the coating. Amorphous coatings are more conformal and reduce lattice mismatch induced epitaxial cracks whereas crystalline coatings are more erosion resistant.

Coating architecture can be a bi-layer or a multi-layer structure. In a bilayer architecture, an amorphous layer can be deposited as a buffer layer to minimize epitaxial cracks followed by a crystalline layer on the top which might be erosion resistant. In a multi-layer design, layer materials may be used to cause a smooth thermal gradient from the substrate to the top layer. Although possible variations in coating architecture are described herein with respect to IAD, it should be understood that such variations may also be accomplished if and/or when the protective coating is deposited by other techniques discussed herein (such as CVD, PVD other than IAD, ALD, and plasma spray) as well as by other techniques understood as equivalent to the techniques enumerated herein by one of ordinary skill in the art.

Co-deposition of multiple materials using multiple electron beam (e-beam) guns can be achieved to create thicker coatings as well as layered architectures. For example, two material sources having the same material type may be used at the same time. This may increase a deposition rate and a thickness of the protective coat. In another example, two material sources may be different ceramic materials or different metallic materials. A first electron beam gun may bombard a first material source to deposit a first protective coat, and a second electron beam gun may subsequently bombard the second material source to form a second protective coat having a different material composition than the first protective coat. Alternatively, the two electron beam guns may bombard the two material sources simultaneously to create a complex ceramic compound. Accordingly, two different metallic targets may be used rather than a single metal alloy to form a complex ceramic compound. Although co-deposition is described herein with respect to IAD, it should be understood that such co-deposition may also be accomplished if and/or when the protective coating is deposited by other techniques discussed herein (such as CVD, PVD other than IAD, ALD, and plasma spray) as well as by other techniques understood as equivalent to the techniques enumerated herein by one of ordinary skill in the art.

Post coating heat treatment can be used to achieve improved coating properties. For example, it can be used to convert an amorphous coating to a crystalline coating with higher erosion resistance. Although post coating heat treatment is described herein with respect to IAD, it should be understood that such post coating heat treatment may also be accomplished if and/or when the protective coating is deposited by other techniques discussed herein (such as CVD, PVD other than IAD, ALD, and plasma spray) as well as by other techniques understood as equivalent to the techniques enumerated herein by one of ordinary skill in the art.

The IAD apparatus depicted in FIG. 4B may be used to deposit, in accordance with the IAD mechanism depicted in FIG. 4A, a protective coat that is resistant to erosion and/or corrosion in embodiments. Protective coat 415 may comprise a ceramic material such as Y₂O₃, SiO₂, or any combination thereof including but not limited to a Y₂O₃ and SiO₂ solid solution or multiphase mixture.

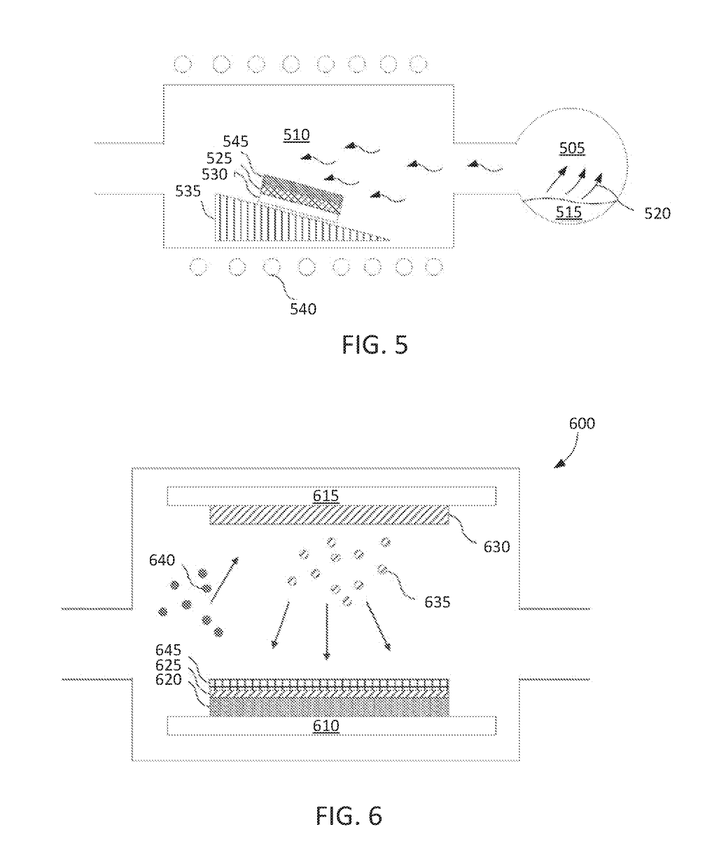

In some embodiments, the protective coating may be deposited on a surface of an article via CVD. An exemplary CVD system is illustrated in FIG. 5. The system comprises a chemical vapor precursor supply system 505 and a CVD reactor 510. The role of the vapor precursor supply system 505 is to generate vapor precursors 520 from a starting material 515, which could be in a solid, liquid, or gas form. The vapors may subsequently be transported into CVD reactor 510 and get deposited as a protective coat 525 and/or 545 on the surface of article 530, in accordance with an embodiment, which may be positioned on article holder 535.

CVD reactor 510 heats article 530 to a deposition temperature using heater 540. In some embodiments, the heater may heat the CVD reactor's wall (also known as “hot-wall reactor”) and the reactor's wall may transfer heat to the article. In other embodiments, the article alone may be heated while maintaining the CVD reactor's wall cold (also known as “cold-wall reactor”). It is to be understood that the CVD system configuration should not be construed as limiting. A variety of equipment could be utilized for a CVD system and the equipment is chosen to obtain optimum processing conditions that may give a coating with uniform thickness, surface morphology, structure, and composition.

The various CVD techniques include the following phases: (1) generate active gaseous reactant species (also known as “precursors”) from the starting material; (2) transport the precursors into the reaction chamber (also referred to as “reactor”); (3) absorb the precursors onto the heated article; (4) participate in a chemical reaction between the precursor and the article at the gas-solid interface to form a deposit and a gaseous by-product; and (5) remove the gaseous by-product and unreacted gaseous precursors from the reaction chamber.

Suitable CVD precursors may be stable at room temperature, may have low vaporization temperature, can generate vapor that is stable at low temperature, have suitable deposition rate (low deposition rate for thin film coatings and high deposition rate for thick film coatings), relatively low toxicity, be cost effective, and relatively pure. For some CVD reactions, such as thermal decomposition reaction (also known as “pyrolysis”) or a disproportionation reaction, a chemical precursor alone may suffice to complete the deposition. For other CVD reactions, other agents (listed in Table 1 below) in addition to a chemical precursor may be utilized to complete the deposition.

TABLE 1
Chemical Precursors and Additional Agents Utilized in
Various CVD Reactions

| CVD reaction | Chemical Precursor | Additional Agents |
|---|---|---|
| Thermal Decomposition | Halides | N/A |
| (Pyrolysis) | Hydrides | |
| | Metal carbonyl | |
| | Metalorganic | |
| Reduction | Halides | Reducing agent |
| Oxidation | Halides | Oxidizing agent |
| | Hydrides | |
| | Metalorganic | |
| Hydrolysis | Halides | Hydrolyzing agent |
| Nitridation | Halides | Nitriding agent |
| | Hydrides | |
| | Halohydrides | |
| Disproportionation | Halides | N/A |

CVD has many advantages including its capability to deposit highly dense and pure coatings and its ability to produce uniform films with good reproducibility and adhesion at reasonably high deposition rates. Layers deposited using CVD in embodiments may have a porosity of below 1%, and a porosity of below 0.1% (e.g., around 0%). Therefore, it can be used to uniformly coat complex shaped components and deposit conformal films with good conformal coverage (e.g., with substantially uniform thickness). CVD may also be utilized to deposit a film made of a plurality of components, for example, by feeding a plurality of chemical precursors at a predetermined ratio into a mixing chamber and then supplying the mixture to the CVD reactor system.

The CVD reactor 510 may be used to form a protective coat that is resistant to erosion and/or corrosion in embodiments. Protective coat 525 and/or 545 may comprise a ceramic material such as Y₂O₃, SiO₂, or any combination thereof including but not limited to a Y₂O₃ and SiO₂ solid solution or multiphase mixture. The protective coat may comprise a bilayer or a multilayer architecture, various layers may have similar or different thicknesses, and the layers may independently be crystalline or amorphous. The materials forming the protective coat may be co-deposited. In some embodiments, the protective coat may be subject to post coating heat treatment. In some embodiments, the protective coat may be subject to post coating processing to form one or more features therein.

In some embodiments, the protective coating may be deposited on a surface of an article via a PVD technique (other than the IAD technique discussed earlier). PVD processes may be used to deposit thin films with thicknesses ranging from a few nanometers to several micrometers. The various PVD processes share three fundamental features in common: (1) evaporating the material from a solid source with the assistance of high temperature or gaseous plasma; (2) transporting the vaporized material in vacuum to the article's surface; and (3) condensing the vaporized material onto the article to generate a thin film layer. An illustrative PVD reactor is depicted in FIG. 6 and discussed in more detail below.

FIG. 6 depicts a deposition mechanism applicable to a variety of PVD techniques and reactors. PVD reactor chamber 600 may comprise a plate 610 adjacent to the article 620 and a plate 615 adjacent to the target 630. Air may be removed from reactor chamber 600, creating a vacuum. Then argon gas may be introduced into the reactor chamber, voltage may be applied to the plates, and a plasma comprising electrons and positive argon ions 640 may be generated. Positive argon ions 640 may be attracted to negative plate 615 where they may hit target 630 and release atoms 635 from the target. Released atoms 635 may get transported and deposited as a thin film protective coat 625 and/or 645 onto article 620, in accordance with an embodiment.

The PVD reactor chamber 600 may be used to form a protective ceramic material coat in embodiments. Protective coat 625 and/or 645 may comprise a ceramic material such as Y₂O₃, SiO₂, or any combination thereof including but not limited to a Y₂O₃ and SiO₂ solid solution or multiphase mixture. The protective coat may comprise a bilayer or a multilayer architecture, various layers may have similar or different thicknesses, and the layers may independently be crystalline or amorphous. The materials forming the protective coat may be co-deposited. In some embodiments, the protective coat may be subject to post coating heat treatment. In some embodiments, the protective coat may be subject to post coating processing to form one or more features therein.

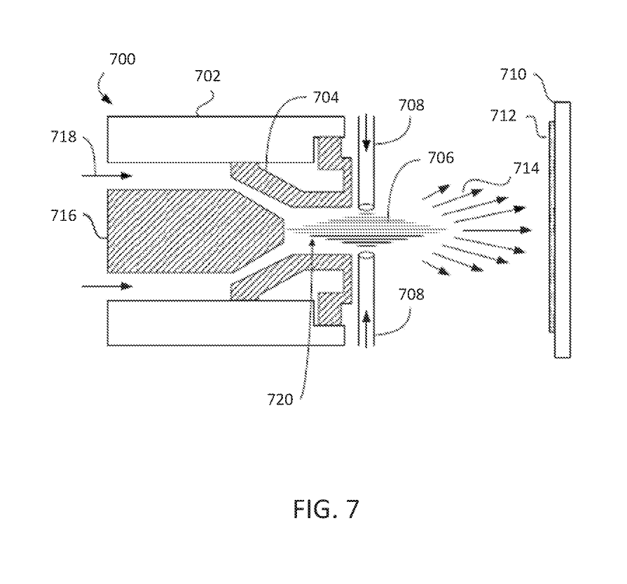

FIG. 7 illustrates a cross-sectional view of a system 700 for plasma spraying a coating on an article. The system 700 is a type of thermal spray system. In a plasma spray system 700, an arc 706 is formed between two electrodes, an anode 704 and a cathode 716, through which a plasma gas 718 is flowing via a gas delivery tube 702. The plasma gas 718 may be a mixture of two or more gases. Examples of gas mixtures suitable for use in the plasma spray system 700 include, but are not limited to, argon/hydrogen, argon/helium, nitrogen/hydrogen, nitrogen/helium, or argon/oxygen. The first gas (gas before the forward-slash) represents a primary gas and the second gas (gas after the forward-slash) represents a secondary gas. A gas flow rate of the primary gas may differ from a gas flow rate of the secondary gas. In one embodiment, a gas flow rate for the primary gas is about 30 L/min and about 400 L/min. In one embodiment, a gas flow rate for the secondary gas is between about 3 L/min and about 100 L/min.

As the plasma gas is ionized and heated by the arc 706, the gas expands and is accelerated through a shaped nozzle 720, creating a high velocity plasma stream.

Powder 708 is injected into the plasma spray or torch (e.g., by a powder propellant gas) where the intense temperature melts the powder and propels the material as a stream of molten particles 714 towards the article 710. Upon impacting the article 710, the molten powder flattens, rapidly solidifies, and forms a coating 712, which adheres to the article 710. Coating 712 may be a protective ceramic material coating according to an embodiment. The parameters that affect the thickness, density, and roughness of the coating 712 include type of powder, powder size distribution, powder feed rate, plasma gas composition, plasma gas flow rate, energy input, torch offset distance, substrate cooling, etc.

Plasma spray apparatus 700 may be used to form a protective ceramic material coat in embodiments. Protective coat 712 may comprise a ceramic material such as Y₂O₃, SiO₂, or any combination thereof including but not limited to a Y₂O₃ and SiO₂ solid solution or multiphase mixture. The protective coat may comprise a bilayer or a multilayer architecture, various layers may have similar or different thicknesses, and the layers may independently be crystalline or amorphous. The materials forming the protective coat may be co-deposited. In some embodiments, the protective coat may be subject to post coating heat treatment. In some embodiments, the protective coat may be subject to post coating processing to form one or more features therein.

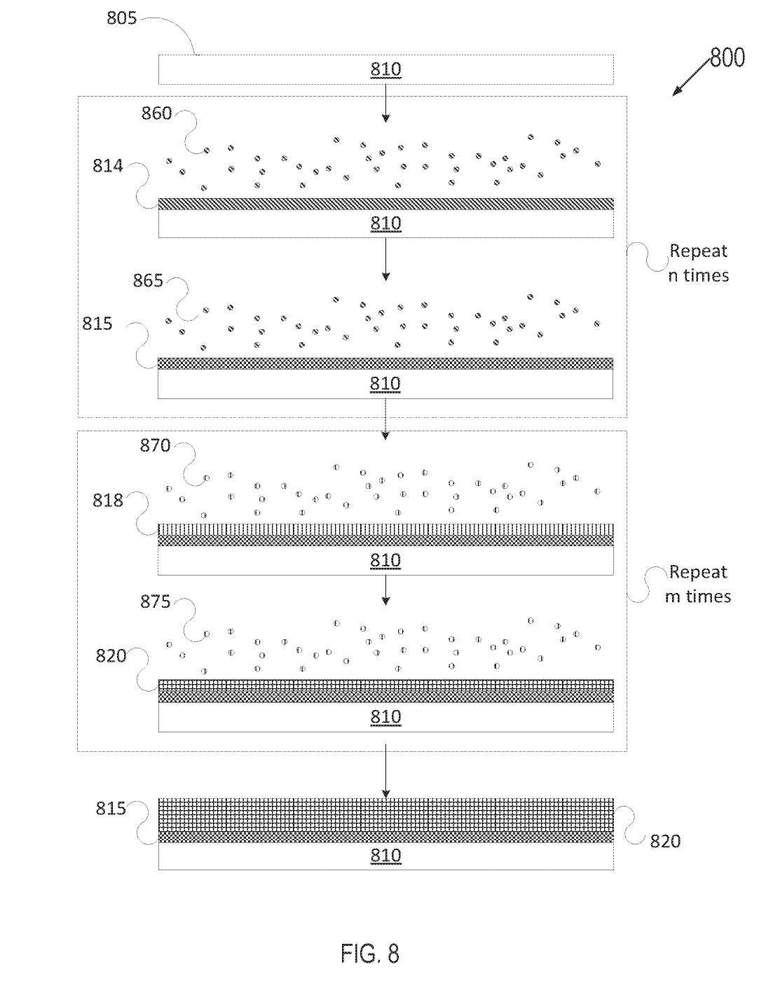

FIG. 8 depicts a deposition process in accordance with a variety of ALD techniques. Various types of ALD processes exist and the specific type may be selected based on several factors such as the surface to be coated, the coating material, chemical interaction between the surface and the coating material, etc. The general principle of an ALD process comprises growing or depositing a thin film layer by repeatedly exposing the surface to be coated to sequential alternating pulses of gaseous chemical precursors that chemically react with the surface one at a time in a self-limiting manner.

FIG. 8 illustrates an article 810 having a surface 805. Each individual chemical reaction between a precursor and the surface is known as a “half-reaction.” During each half reaction, a precursor is pulsed onto the surface for a period of time sufficient to allow the precursor to fully react with the surface. The reaction is self-limiting as the precursor will react with a finite number of available reactive sites on the surface, forming a uniform continuous adsorption layer on the surface. Any sites that have already reacted with a precursor will become unavailable for further reaction with the same precursor unless and/or until the reacted sites are subjected to a treatment that will form new reactive sites on the uniform continuous coating. Exemplary treatments may be plasma treatment, treatment by exposing the uniform continuous adsorption layer to radicals, or introduction of a different precursor able to react with the most recent uniform continuous film layer adsorbed to the surface.

In FIG. 8, article 810 having surface 805 may be introduced to a first precursor 860 for a first duration until a first half reaction of the first precursor 860 with surface 805 partially forms film layer 815 by forming an adsorption layer 814. Subsequently, article 810 may be introduced to a first reactant 865 that reacts with the adsorption layer 814 to fully form the layer 815. The first precursor 860 may be a precursor for yttrium, a precursor for silicon, or another metal, for example. The first reactant 865 may be an oxygen reactant if the layer 815 is an oxide (e.g. yttria, silica, or a combination thereof). The article 810 may also be exposed to the first precursor 860 and first reactant 865 up to n number of times to achieve a target thickness for the layer 815. n may be an integer from 1 to 100, for example.

Film layer 815 may be a uniform, continuous and conformal. The film layer 815 may also have a very low porosity of less than 1% in embodiments, less than 0.1% in some embodiments, or approximately 0% in further embodiments. Subsequently, article 810 having surface 805 and film layer 815 may be introduced to a second precursor 870 that reacts with layer 815 to partially form a second film layer 820 by forming a second adsorption layer 818. Subsequently, article 810 may be introduced to another reactant 875 that reacts with adsorption layer 818 leading to a second half reaction to fully form the layer 820. The article 810 may alternately be exposed to the second precursor 870 and second reactant 875 up to m number of times to achieve a target thickness for the layer 820. m may be an integer from 1 to 100, for example. The second film layer 820 may be uniform, continuous and conformal. The second film layer 820 may also have a very low porosity of less than 1% in some embodiments, less than 0.1% in some embodiments, or approximately 0% in further embodiments.

In a similar manner, article 810 may continue to be introduced sequentially to the same or to other precursors and reactants until a final protective ceramic material coating according to an embodiment is formed.

In one embodiment, the final protective ceramic material coating may comprise a bilayer or a multilayer architecture of yttria and silica. In one embodiment, the final protective ceramic material coating may have alternating layers of yttria and silica. In one embodiment, the alternating layers of yttria and silica may have the same or different thickness. The layers may independently be crystalline or amorphous.

In certain embodiments, the ALD deposition may comprise exposing article, e.g., article 810, to multiple precursors, e.g. a yttrium-containing precursor and a silicon-containing precursor, and co-depositing the different precursors simultaneously. The ratio of the yttrium-containing precursor and the silicon-containing precursor may be selected to achieve a desired coating composition. Subsequently, article 810 may be exposed to a reactant such as an oxygen-containing reactant to form a final protective ceramic material coating comprising a plurality of oxides (e.g., yttria and silica).

In certain embodiments, the bilayer, multilayer, and/or co-deposited layer forming the final protective ceramic material coating may be annealed and/or interdiffused, for instance, through post-coating heat treatment. In embodiments the annealing process causes the Si and Y to interdiffuse between the alternating SiO₂ and Y₂O₃ layers and form a uniform coating of a Y₂O₃—SiO₂ solid solution or a multiphase mixture. In some embodiments, a post deposition annealing process is not performed and instead already deposited SiO₂ and Y₂O₃ layers interdiffuse during deposition of subsequent layers. In some embodiments, the protective coat may be subject to post coating processing to form one or more features therein.

The surface reactions (e.g., half-reactions) described above, such as the reaction between the article's surface and the precursor(s) or the reaction between the precursor(s) and the reactant(s), are done sequentially. Prior to introduction of a new precursor(s) and/or a new reactant(s), the chamber in which the ALD process takes place may be purged with an inert carrier gas (such as nitrogen or air) to remove any unreacted precursors and/or reactants and/or surface-precursor reaction byproducts.

ALD processes may be conducted at various temperatures. The optimal temperature range for a particular ALD process is referred to as the “ALD temperature window.” Temperatures below the ALD temperature window may result in poor growth rates and non-ALD type deposition. Temperatures above the ALD temperature window may result in thermal decomposition of the article or rapid desorption of the precursor. The ALD temperature window may range from about 200° C. to about 400° C. In some embodiments, the ALD temperature window is between about 150° C. to about 350° C.

The ALD process allows for conformal film layers having uniform film thickness on articles and surfaces having complex geometric shapes, holes with large aspect ratios, and three-dimensional structures. Sufficient exposure time of the precursors to the surface enables the precursors to disperse and fully react with the surface in its entirety, including all of its three-dimensional complex features. The exposure time utilized to obtain conformal ALD in high aspect ratio structures is proportionate to the square of the aspect ratio and can be predicted using modeling techniques.

The final protective ceramic material coatings deposited by the ALD process discussed above may comprise a ceramic material such as Y₂O₃, SiO₂, or any combination thereof including but not limited to a Y₂O₃ and SiO₂ solid solution or a multiphase mixture.

Article 410 in FIG. 4A, articles 410A and 410B in FIG. 4B, article 530 in FIG. 5, article 620 in FIG. 6, article 710 in FIG. 7, article 810 in FIG. 8, and all other articles discussed herein may represent various semiconductor process chamber components or other chamber components including but not limited to substrate support assembly, an electrostatic chuck (ESC), an electrostatic chuck component, a ring (e.g., a process kit ring or single ring), a chamber wall, a base, a gas distribution plate, gas lines, a showerhead, a nozzle, a lid, a chamber lid, a liner, a liner kit, a shield, a plasma screen, a flow equalizer, a cooling base, a chamber viewport, a chamber lid, and so on. The articles and their surfaces may be made from a metal (such as aluminum, stainless steel), a ceramic, a metal-ceramic composite, a polymer, a polymer ceramic composite, or other suitable materials, and may further comprise materials such as AlN, Si, SiC, Al₂O₃, SiO₂, and so on.

With the IAD, CVD, PVD, ALD, and plasma spray techniques, protective ceramic material coatings comprising Y₂O₃, SiO₂, or any combination thereof including but not limited to a Y₂O₃ and SiO₂ solid solution or a multiphase mixture, can be formed. The protective ceramic material coatings disclosed herein provide good erosion and/or corrosion resistance to the coated article. Additionally, there is a reduced likelihood of yttrium metal contamination on substrates that may get processed in chambers comprising chamber components coated with the protective ceramic material coatings disclosed herein. The beneficial properties of the protective ceramic material coatings disclosed herein may be independent from the deposition techniques in certain embodiments. In certain embodiments, the beneficial properties observed in a protective coating deposited by CVD, PVD other than IAD, ALD, and/or plasma spray may be comparable or superior to those observed in a protective coating that is deposited by IAD.

Exemplary yttrium-containing precursors that may be utilized with the CVD and ALD coating deposition techniques include, but are not limited to, tris(N,N-bis(trimethylsilyl)amide)yttrium (III), yttrium (III)butoxide, tris(cyclopentadienyl)yttrium(III), and Y(thd)3 (thd=2,2,6,6-tetramethyl-3,5-heptanedionato).

Exemplary silicon-containing precursors that may be utilized with the ALD and CVD coating deposition techniques include, but are not limited to, 2, 4, 6, 8-tetramethylcyclotetrasiloxane, dimethoxydimethylsilane, disilane, methylsilane, octamethylcyclotetrasiloxane, silane, tris(isopropoxy)silanol, tris(tert-butoxy)silanol, and tris (tert-pentoxy) silanol.

Exemplary oxygen-containing reactants that may be utilized with the various coating deposition techniques identified herein and their equivalent include, but are not limited to, ozone, water vapor, and oxygen radicals.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular embodiments may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.”

Reference throughout this specification to numerical ranges should not be construed as limiting and should be understood as encompassing the outer limits of the range as well as each number and/or narrower range within the enumerated numerical range.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A semiconductor process chamber component comprising:
an article; and
a protective ceramic material coating comprising at least one phase material, wherein the at least one phase material comprises Y₂O₃ at a concentration of about 10 molar % to about 65 molar % and SiO₂ at a concentration of about 35 molar % to about 90 molar %.

2. The semiconductor process chamber component of claim 1, wherein the article is selected from a group consisting of an electrostatic chuck, a nozzle, a gas distribution plate, a shower head, an electrostatic chuck component, a chamber wall, a liner, a liner kit, a chamber lid, a single ring, a gas line, and a processing kit ring.

3. The semiconductor process chamber component of claim 1, wherein the at least one phase material comprises Y₂O₃ at a concentration of about 20 molar % to about 60 molar % and SiO₂ at a concentration of about 40 molar % to about 80 molar %.

4. The semiconductor process chamber component of claim 1, wherein the at least one phase material comprises Y₂O₃ at a concentration of about 25 molar % to about 55 molar % and SiO₂ at a concentration of about 45 molar % to about 75 molar %.

5. The semiconductor process chamber component of claim 1, wherein the at least one phase material comprises Y₂O₃ at a concentration of about 40 molar % to about 50 molar % and SiO₂ at a concentration of about 50 molar % to about 60 molar %.

6. The semiconductor process chamber component of claim 1, wherein the at least one phase material comprises a composition selected from the group consisting of:
a) Y₂O₃ at a concentration of about 65 molar % and SiO₂ at a concentration of about 35 molar %,
b) Y₂O₃ at a concentration of about 60 molar % and SiO₂ at a concentration of about 40 molar %,
c) Y₂O₃ at a concentration of about 55 molar % and SiO₂ at a concentration of about 45 molar %,
d) Y₂O₃ at a concentration of about 50 molar % and SiO₂ at a concentration of about 50 molar %,
e) Y₂O₃ at a concentration of about 45 molar % and SiO₂ at a concentration of about 55 molar %,
f) Y₂O₃ at a concentration of about 40 molar % and SiO₂ at a concentration of about 60 molar %,
g) Y₂O₃ at a concentration of about 35 molar % and SiO₂ at a concentration of about 65 molar %,
h) Y₂O₃ at a concentration of about 30 molar % and SiO₂ at a concentration of about 70 molar %,
i) Y₂O₃ at a concentration of about 25 molar % and SiO₂ at a concentration of about 75 molar %,
j) Y₂O₃ at a concentration of about 20 molar % and SiO₂ at a concentration of about 80 molar %,
k) Y₂O₃ at a concentration of about 15 molar % and SiO₂ at a concentration of about 85 molar %, and
l) Y₂O₃ at a concentration of about 10 molar % and SiO₂ at a concentration of about 90 molar %.

7. The semiconductor process chamber component of claim 1, wherein the concentration of Y₂O₃ and of SiO₂ adds up to 100 molar %.

8. A method comprising:
creating a mixture of ceramic powders comprising Y₂O₃ at a concentration of about 10 molar % to about 65 molar % and SiO₂ at a concentration of about 35 molar % to about 90 molar % to form a protective ceramic material coating; and
coating an article with the protective ceramic material coating.

9. The method of claim 8, wherein the article is selected from a group consisting of an electrostatic chuck, a lid, a nozzle, a gas distribution plate, a shower head, an electrostatic chuck component, a chamber wall, a liner, a liner kit, a chamber lid, a single ring, a gas line, and a processing kit ring.

10. The method of claim 8, further comprising:
forming one or more features in the protective ceramic material coating, the one or more features comprising at least one of holes, channels or mesas.

11. The method of claim 8, wherein the mixture of ceramic powders comprises Y₂O₃ at a concentration of about 20 molar % to about 60 molar % and SiO₂ at a concentration of about 40 molar % to about 80 molar %.

12. The method of claim 8, wherein the mixture of ceramic powders comprises Y₂O₃ at a concentration of about 25 molar % to about 55 molar % and SiO₂ at a concentration of about 45 molar % to about 75 molar %.

13. The method of claim 8, wherein the coating comprises depositing the protective ceramic material coating by a technique selected from the group consisting of ion assisted deposition, chemical vapor deposition, physical vapor deposition, atomic layer deposition, and plasma spray.

14. The method of claim 8, wherein the mixture of ceramic powders comprises a composition selected from the group consisting of:
a) Y₂O₃ at a concentration of about 65 molar % and SiO₂ at a concentration of about 35 molar %,
b) Y₂O₃ at a concentration of about 60 molar % and SiO₂ at a concentration of about 40 molar %,
c) Y₂O₃ at a concentration of about 55 molar % and SiO₂ at a concentration of about 45 molar %,
d) Y₂O₃ at a concentration of about 50 molar % and SiO₂ at a concentration of about 50 molar %,
e) Y₂O₃ at a concentration of about 45 molar % and SiO₂ at a concentration of about 55 molar %,
f) Y₂O₃ at a concentration of about 40 molar % and SiO₂ at a concentration of about 60 molar %,
g) Y₂O₃ at a concentration of about 35 molar % and SiO₂ at a concentration of about 65 molar %,
h) Y₂O₃ at a concentration of about 30 molar % and SiO₂ at a concentration of about 70 molar %,
i) Y₂O₃ at a concentration of about 25 molar % and SiO₂ at a concentration of about 75 molar %,
j) Y₂O₃ at a concentration of about 20 molar % and SiO₂ at a concentration of about 80 molar %,
k) Y₂O₃ at a concentration of about 15 molar % and SiO₂ at a concentration of about 85 molar %, and
l) Y₂O₃ at a concentration of about 10 molar % and SiO₂ at a concentration of about 90 molar %.

15. A semiconductor process chamber component coating comprising at least one phase material, wherein the at least one phase material comprises Y₂O₃ at a concentration of about 10 molar % to about 65 molar % and SiO₂ at a concentration of about 35 molar % to about 90 molar %.

16. The semiconductor process chamber component coating of claim 15, wherein the at least one phase material comprises Y₂O₃ at a concentration of about 20 molar % to about 60 molar % and SiO₂ at a concentration of about 40 molar % to about 80 molar %.

17. The semiconductor process chamber component coating of claim 15, wherein the at least one phase material comprises Y₂O₃ at a concentration of about 25 molar % to about 55 molar % and SiO₂ at a concentration of about 45 molar % to about 75 molar %.

18. The semiconductor process chamber component coating of claim 15, wherein the at least one phase material comprises Y₂O₃ at a concentration of about 40 molar % to about 50 molar % and SiO₂ at a concentration of about 50 molar % to about 60 molar %.

19. The semiconductor process chamber component coating of claim 15, wherein the at least one phase material comprises a composition selected from the group consisting of:
a) Y₂O₃ at a concentration of about 65 molar % and SiO₂ at a concentration of about 35 molar %,
b) Y₂O₃ at a concentration of about 60 molar % and SiO₂ at a concentration of about 40 molar %,
c) Y₂O₃ at a concentration of about 55 molar % and SiO₂ at a concentration of about 45 molar %,
d) Y₂O₃ at a concentration of about 50 molar % and SiO₂ at a concentration of about 50 molar %,
e) Y₂O₃ at a concentration of about 45 molar % and SiO₂ at a concentration of about 55 molar %,
f) Y₂O₃ at a concentration of about 40 molar % and SiO₂ at a concentration of about 60 molar %,
g) Y₂O₃ at a concentration of about 35 molar % and SiO₂ at a concentration of about 65 molar %,
h) Y₂O₃ at a concentration of about 30 molar % and SiO₂ at a concentration of about 70 molar %,
i) Y₂O₃ at a concentration of about 25 molar % and SiO₂ at a concentration of about 75 molar %,
j) Y₂O₃ at a concentration of about 20 molar % and SiO₂ at a concentration of about 80 molar %,
k) Y₂O₃ at a concentration of about 15 molar % and SiO₂ at a concentration of about 85 molar %, and
l) Y₂O₃ at a concentration of about 10 molar % and SiO₂ at a concentration of about 90 molar %.

20. The semiconductor process chamber component coating of claim 15, wherein the concentration of Y₂O₃ and of SiO₂ adds to 100 molar %.
